(19) United States
(12) Patent Application Publication
(10) Pub. No.: US 2025/0018528 A1
(43) Pub. Date: Jan. 16, 2025

(54) PROCESSING METHOD FOR WORKPIECE

(71) Applicant: DISCO CORPORATION, Tokyo (JP)

(72) Inventors: Hayato KIUCHI, Tokyo (JP); Chitose YAMADA, Tokyo (JP)

(73) Assignee: DISCO CORPORATION, Tokyo (JP)

(21) Appl. No.: 18/761,416

(22) Filed: Jul. 2, 2024

(30) Foreign Application Priority Data
Jul. 10, 2023 (JP) 2023-112812

(51) Int. Cl. B24B 41/06; B24C 9/00

(52) U.S. Cl. CPC B24B 41/06; B24C 9/00

(57) ABSTRACT

A processing method for a workpiece is provided. The method includes preparing the workpiece by fixing a surface of the workpiece on one side to a support member, the workpiece having a division groove formed therein along a division preparatory line; reducing a width of the division groove by applying external force to at least a region of the support member corresponding to the division groove to cause shrinkage in the support member; and removing a burr from the workpiece by injecting high-pressure water along the division groove from the other side of the workpiece.

### CROSS REFERENCE TO RELATED APPLICATION

This application is based upon and claims the benefit of priority from the prior Japanese Patent Application No. 2023-112812, filed on Jul. 10, 2023; the entire contents of which are incorporated herein by reference.

### FIELD

The present invention relates to a processing method for a workpiece.

### BACKGROUND

In a processing method of manufacturing a plurality of chips by dividing a workpiece, when the workpiece is divided into a plurality of chips using a cutting blade or the like, a burr may be created on an edge of a division groove (kerf). For example, when the workpiece is a semiconductor workpiece such as a package substrate, the burr may cause a connection failure when a chip obtained by dividing the workpiece is mounted on a substrate or the like. Therefore, it is desirable to remove the burr, and a method of removing the burr created in the workpiece by injecting high-pressure water is known (for example, Japanese Patent Publication No. 2019-206048 A).

When a burr is removed by injecting high-pressure water, it is required to reliably remove the burr without damaging peripheral structures other than the burr. For example, when the pressure to inject water is increased, the burr may be easily removed, but there is a risk that the high-pressure water hits a sheet (tape) that supports the workpiece or a holding surface of a holding table on which the workpiece is placed, and holes may be formed in the sheet or the holding surface, so that the workpiece may not be held correctly. In addition, when the pressure to inject water is lowered, another problem that the burr is not sufficiently removed may arise.

### SUMMARY

The present invention provides a processing method that may prevent damage on a support member that supports a workpiece even when high-pressure water having a pressure suitable for removal of a burr is injected.

A processing method for a workpiece according to an aspect of the present invention includes preparing the workpiece by fixing a surface of the workpiece on one side to a support member, the workpiece having a division groove formed therein along a division preparatory line; reducing a width of the division groove by applying external force to at least a region of the support member corresponding to the division groove to cause shrinkage in the support member; and removing a burr from the workpiece by injecting, after the support member being shrunk, high-pressure water along the division groove from the other side of the workpiece.

Optionally, heat may be applied to the support member to cause the shrinkage.

### BRIEF DESCRIPTION OF THE DRAWINGS

FIG. 1 is a diagram illustrating a semiconductor wafer which is a workpiece.

FIG. 2 is a diagram illustrating a package substrate which is a workpiece.

FIG. 3 is a diagram illustrating a dividing process in a preparation step.

FIG. 4 is a diagram illustrating a first embodiment of a shrinkage step.

FIG. 5 is a diagram illustrating the first embodiment of the shrinkage step.

FIG. 6 is a diagram illustrating a second embodiment of the shrinkage step.

FIG. 7 is a diagram illustrating a deburring step.

### DESCRIPTION OF EMBODIMENTS

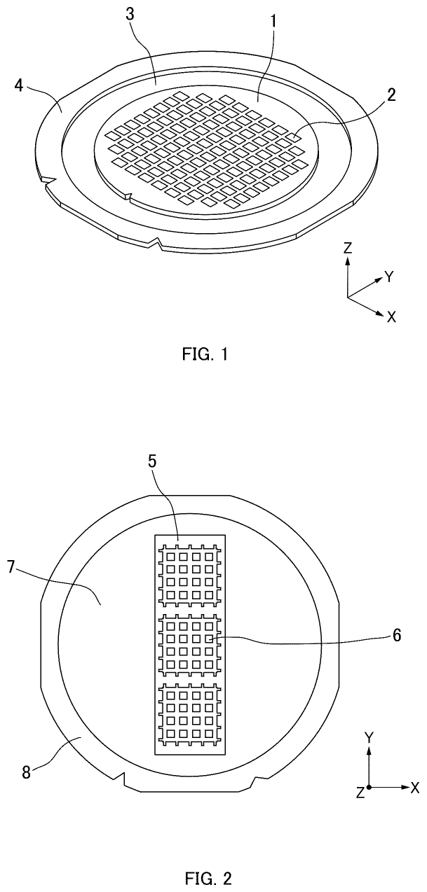

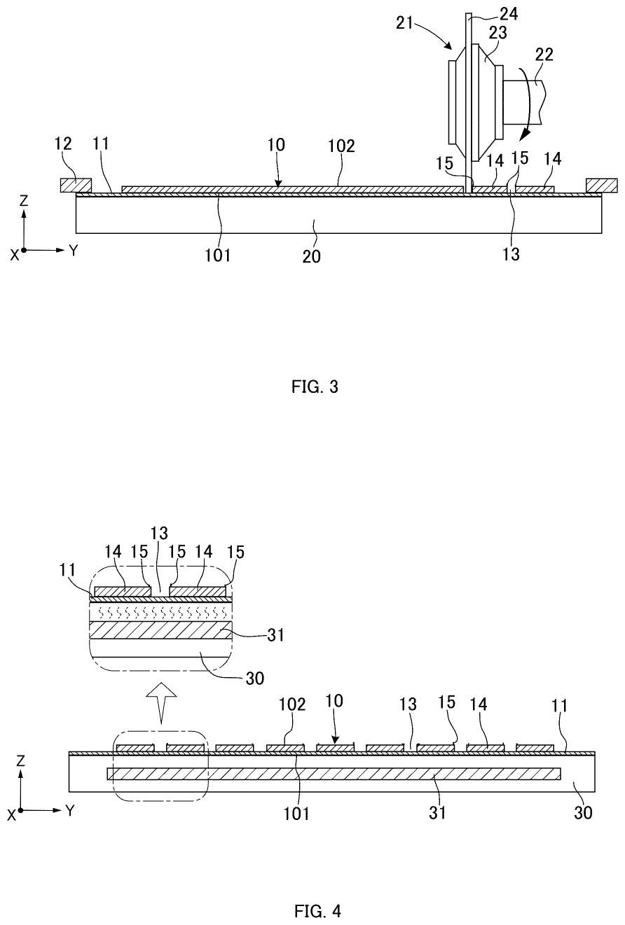

Hereinafter, a processing method for processing a workpiece according to the present embodiment will be described with reference to the accompanying drawings. FIGS. 1 and 2 are diagrams each illustrating an example of a workpiece. FIGS. 3 to 7 are diagrams each illustrating a step in the processing method for the workpiece. An X-axis direction and a Y-axis direction shown in each drawing are horizontal directions, and a Z-axis direction is a vertical direction. The X-axis direction and the Y-axis direction are perpendicular to each other.

A wafer 1 illustrated in FIG. 1 is a disk-shaped semiconductor wafer made of a material such as silicon. On a front surface side of the wafer 1, a chip 2, which is an electronic device, is formed in each of a plurality of regions partitioned by a plurality of division preparatory lines in grid formation. The wafer 1 is supported by an annular frame 4 via a tape 3 which is a support member attached to a back side thereof.

In a package substrate 5 illustrated in FIG. 2, a chip 6, which is an electronic device, is formed in each of a plurality of regions partitioned by a plurality of division preparatory lines in grid formation. The package substrate 5 is supported by an annular frame 8 via a tape 7 which is a support member attached to a back side thereof.

In the processing method for the workpiece according to the present embodiment described below, a plate-like object to be processed, including the wafer 1, the package substrate 5, and the like, is referred to as a workpiece 10, a member corresponding to the tape 3 or the tape 7 is referred to as a support member 11, and a member corresponding to the frame 4 or the frame 8 is referred to as a frame 12.

### [Preparation Step (Dividing Process)]

As illustrated in FIG. 3, in a preparation step, the support member 11 is fixed to one surface 101 on one side of the workpiece 10, and division grooves 13 are formed along the division preparatory lines of the workpiece 10. In the workpiece 10, a surface to which the support member 11 is fixed is defined as the one surface 101, and a surface on the opposite side to the one surface 101 is defined as the other surface 102.

As an example, the support member 11 is an adhesive tape (dicing tape) having a base material layer having flexibility and non-adhesiveness and an adhesive layer laminated on the base material layer and having flexibility and adhesiveness. The support member 11 formed of such an adhesive tape is fixed to the one surface 101 of the workpiece 10 by adhesion of the adhesive layer.

As another example, the support member 11 may be a sheet made of a thermoplastic resin having no adhesive layer. The support member 11 formed of such a non-adhesive sheet is bonded to the one surface 101 of the workpiece 10 by thermocompression bonding. As the non-adhesive sheet, a polyolefin-based sheet, a polyethylene sheet, a polypropylene sheet, and a polystyrene sheet may be preferably used.

As still another example, the support member 11 may be a resin sheet of a type that has fine concavo-convex surface and is tightly pressed against the one surface 101 of the workpiece 10.

Further, the support member 11 is made of a material that has elasticity and shrinks when a predetermined external force is applied thereto. Specifically, the support member 11 of the present embodiment is formed of a heat-shrinkable tape or sheet that shrinks when heated to a predetermined temperature or higher. According to the present embodiment, heating the support member 11 to the predetermined temperature or higher works as applying a predetermined external force to the support member 11 in a shrinkage step, which will be described later.

The frame 12 is made of a highly rigid material such as metal. An area of the support member 11 is larger than an area of the workpiece 10, the workpiece 10 is fixed to the central region of the support member 11, and the frame 12 is fixed to the peripheral region of the support member 11.

FIG. 3 illustrates a dividing process of forming the division groove 13 in the workpiece 10 using a cutting device in the preparation step. In a state in which the frame 12 is fixed to the peripheral region of the support member 11, the workpiece 10 is conveyed to the cutting device. The cutting device includes a holding table 20 that holds the workpiece 10, and a cut-processing assembly 21 that performs cutting to the workpiece 10 held on the holding table 20.

The workpiece 10 is placed on the holding table 20 in a state in which the other surface 102 faces upwards and the support member 11 faces downwards. That is, the support member 11 is placed on an upper surface of the holding table 20, and the workpiece 10 is held on the holding table 20 with the support member 11 interposed therebetween.

The workpiece 10 is fixedly held by the holding table 20. As a method of holding the workpiece 10, for example, the holding table 20 may include a suction structure (not illustrated) that applies suction force to the upper surface thereof. When the suction force is applied to the upper surface of the holding table 20, the support member 11 may be suctioned and held on the upper surface of the holding table 20, and the workpiece 10 fixed to the support member 11 may be fixed to the holding table 20.

As another method of holding the workpiece 10, the holding table 20 may include a clamp portion (not illustrated) that clamps the frame 12. When the frame 12 is clamped by the clamp portion, the workpiece 10 supported by the frame 12 with the support member 11 interposed therebetween is fixed to the holding table 20.

The holding table 20 may hold the workpiece 10 using both the suction structure and the clamp portion.

The cut-processing assembly 21 includes a spindle 22 extending in the Y-axis direction and a cutting blade 24 attached to a tip of the spindle 22 with a mount 23 interposed therebetween. The cutting blade 24 is an annular cutter. The spindle 22 is rotated by a motor (not illustrated), and the cutting blade 24 rotates integrally with the spindle 22.

The holding table 20 and the cut-processing assembly 21 are relatively movable in the X-axis direction and the Y-axis direction. For example, the holding table 20 may be configured to move in the X-axis direction, and the cut-processing assembly 21 may be configured to move in the Y-axis direction. Moreover, the cut-processing assembly 21 is movable in the Z-axis direction. When the cut-processing assembly 21 is moved downwards in the Z-axis direction while the workpiece 10 is held on the holding table 20, a lower edge of the cutting blade 24 approaches the workpiece 10. When the cut-processing assembly 21 is moved downwards in a state in which the cutting blade 24 is rotated by driving of the spindle 22, the cutting blade 24 may slit the workpiece 10 from the other surface 102 through the workpiece 10 so as to form the division groove 13 in the workpiece 10, as illustrated in FIG. 3.

When the division groove 13 is formed in the workpiece 10 using the cutting device, the cutting blade 24 is positioned above a starting point of a division preparatory line extending in the X-axis direction. Then, the cut-processing assembly 21 is moved downwards while the cutting blade 24 is rotated, and the cutting blade 24 cuts the workpiece at the starting point of the division preparatory line at a predetermined depth. Subsequently, the holding table 20 and the cut-processing assembly 21 are relatively moved in the X-axis direction until the cutting blade 24 reaches an ending point of the division preparatory line. In this manner, the division groove 13 is formed along one of the division preparatory lines extending in the X-axis direction.

When the division grooves 13 are formed along one of the division preparatory lines, the holding table 20 and the cut-processing assembly 21 are relatively moved in the Y-axis direction, and the cutting blade 24 is positioned above a starting point of a next one of the division preparatory lines extending in the X-axis direction. Thereafter, the rotating cutting blade 24 cuts the workpiece 10 from the starting point of the division preparatory line, and the holding table 20 and the cut-processing assembly 21 are relatively moved in the X-axis direction until the cutting blade 24 reaches an ending point of the division preparatory line. In this manner, the division groove 13 is formed along the next one of the division preparatory lines extending in the X-axis direction.

When the division grooves 13 are completely formed along all the division preparatory lines extending in the X-axis direction, the holding table 20 is rotated by 90°. Accordingly, the plurality of division preparatory lines that are not yet cut extend in the X-axis direction (arrayed at intervals in the Y-axis direction), cutting with the cutting blade 24 is performed along the respective division preparatory lines extending in the X-axis direction so as to form the division grooves 13 in the same procedure as described above.

The dividing process is performed such that the division grooves 13 are formed into a full-cut groove penetrating the workpiece 10 in the Z-axis direction. Therefore, the support member 11 is exposed at bottoms of the division grooves 13.

The workpiece 10 includes chips 14 (corresponding to the chip 2 in FIG. 1 and the chip 6 in FIG. 2) in a plurality of regions partitioned in grid formation by the division grooves 13. When the division groove 13 is formed in the workpiece 10 in the preparation step, a burr 15, which is a processing residue, may be created along the edge of the division groove 13. In particular, the burr 15 is easily formed so as to protrude on the other surface 102 on which cutting of the cutting blade 24 is performed. Since the burr 15 may cause a connection failure of the chip 14 or the like after being assembled and may cause deterioration in quality of the device, it is necessary to remove the burr 15 in order to obtain the chip 14 in a qualified condition.

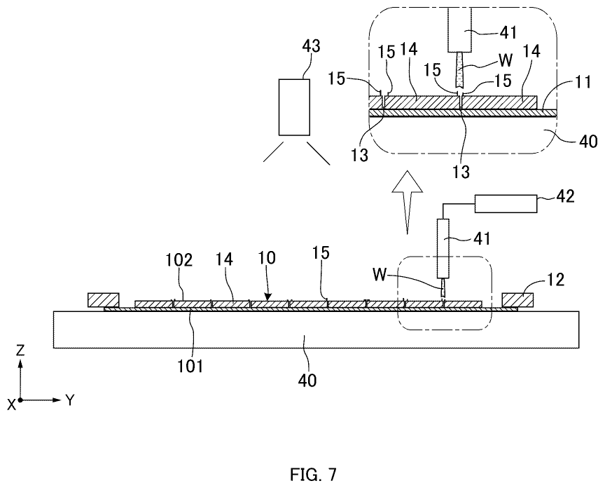

When a water jet type processing device (FIG. 7) as described later is used for removing the burr 15, high-pressure water is injected toward the workpiece 10. However, as illustrated in FIG. 3, the division groove 13 at the circumstance of being divided by the cutting blade 24 or the like of the cut-processing assembly 21 has a predetermined width between two adjacent chips 14. The division groove 13 is a full-cut groove penetrating the workpiece 10 in the Z-axis direction (thickness direction). Therefore, when high-pressure water having an increased pressure suitable for removal of the burr 15 is injected immediately after the dividing process toward the division groove 13, which is widened by the dividing process, the high-pressure water may passe through the division groove 13 and hit the support member 11 (an exposed region of the support member 11 corresponding to the division groove 13). The support member 11 is made of a material having elasticity and relatively low rigidity as compared with the workpicce 10. Therefore, when the injected high-pressure water hits the support member 11, damage such as a hole being formed in the support member 11 is likely to occur. When the support member 11 is damaged, the workpiece 10 may not be held correctly, and processing and conveyance of the workpiece 10 thereafter may be hindered.

### [Shrinkage Step]

In order to solve such a problem, a shrinkage step is performed following the preparation step. In the shrinkage step, external force is applied to at least a region of the support member 11 corresponding to the division groove 13 to cause shrinkage and reduce the width of the division groove 13. Applying the external force to at least the region of the support member 11 corresponding to the division groove 13 means that the external force may be either applied or not applied to a region of the support member 11 corresponding to the chip 14 between the division grooves 13. It is noted that a concept of reducing the width of the division groove 13 includes an arrangement, in which the edges of the adjacent chips 14 contact each other with the width of the division groove 13 being substantially 0, and an arrangement, in which the edges of the adjacent chips 14 do not contact each other and some width remains in the division groove 13. That is, the shrinkage step only needs to make the width of the division groove 13 smaller than the width of the division groove 13 immediately after the dividing process by a predetermined amount or more.

In particular, in the shrinkage step, the width of the division groove 13 preferably shrinks to be equal to a nozzle diameter of a high-pressure water injection nozzle 41 (FIG. 7) used in a burr removal step to be described later, and more preferably shrinks to be smaller than the nozzle diameter of the high-pressure water injection nozzle 41. Since high-pressure water W injected from the high-pressure water injection nozzle 41 has an injection range wider than the nozzle diameter of the high-pressure water injection nozzle 41 when reaching the workpiece 10, the support member 11 may be effectively protected from the pressure of the high-pressure water W by causing the width of the division groove 13 to shrink so as to have the same size as that of the nozzle diameter of the high-pressure water injection nozzle 41. Furthermore, by causing the width of the division groove 13 to shrink so as to have a width smaller than the nozzle diameter of the high-pressure water injection nozzle 41, the support member 11 may be reliably prevented from being hit directly by the high-pressure water W injected from the high-pressure water injection nozzle 41.

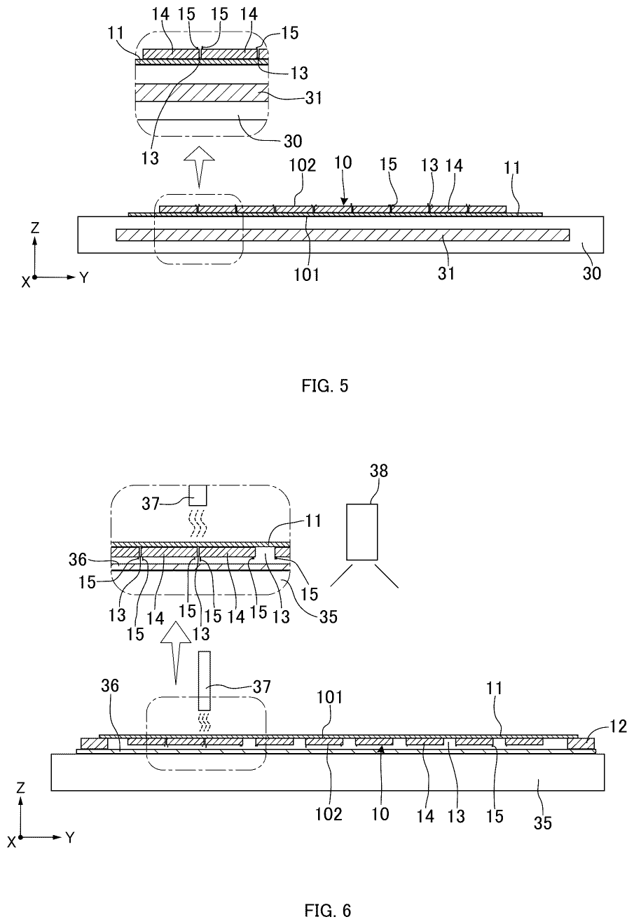

FIGS. 4 and 5 are diagrams each showing a first embodiment of the shrinkage step, and FIG. 6 is a diagram showing a second embodiment of the shrinkage step. As described above, the support member 11 is formed of a heat-shrinkable tape or sheet that shrinks when heated to a predetermined temperature or higher. The first embodiment and the second embodiment of the shrinkage step are common in that heating is performed for applying a predetermined external force to the support member 11, and the support member 11 shrinks by being heated. In the shrinkage step, the support member 11 is supported movably in the horizontal direction relative to holding tables 30 and 35 to be described later. In other words, in the shrinkage step, the support member 11 is not fixed to the holding tables 30 and 35.

As illustrated in FIGS. 4 and 5, in the first embodiment of the shrinkage step, the holding table 30 incorporating a heater 31 serving as a heat source is provided, and the workpiece 10 and the support member 11 are placed on the holding table 30. Specifically, the lower surface of the support member 11 is placed on the upper surface of the holding table 30 in a state in which the other surface 102 of the workpiece 10 faces upwards and the support member 11 faces downwards.

It is noted that, in a case where an overall amount of shrinkage of the support member 11 increases, such as a case in which the number of the division grooves 13 is large, when the frame 12 remains attached to the support member 11 in the shrinkage step, tension between the support member 11 and the frame 12 may partially reach a limit, and the support member 11 may be hindered from shrinking sufficiently. Therefore, in the first embodiment of the shrinkage step, as illustrated in FIGS. 4 and 5, the workpiece 10 and the support member 11 are placed on the holding table 30 in a state in which the frame 12 is removed from the support member 11. However, depending on conditions such as the number of the division grooves 13 and the amount of shrinkage, even when the support member 11 is attached to the frame 12, by increasing the tension in the support member 11, the potential insufficient shrinkage may be overcome, and the frame 12 may not be hindered from shrinking. In such a case, the shrinkage step may be performed in a state in which the frame 12 is attached to the support member 11.

When a setting of the workpiece 10 and the support member 11 with respect to the holding table 30 is completed as illustrated in FIG. 4, the heater 31 is operated to generate heat. Then, the heat is transferred from the heater 31 to the support member 11 via the holding table 30, and the support member 11 receiving the heat shrinks in the horizontal direction, as illustrated in FIG. 5. When the support member 11 shrinks, an interval between the plurality of chips 14 supported on the support member 11 decreases, and the width of the division groove 13 decreases.

The heater 31 has a substantial area corresponding to the workpiece 10, and when the heater 31 generates heat, heat regions corresponding to the plurality of division grooves 13 may be collectively heated, and a wide range of the support member 11 may shrink in a short time. Since the heater 31 is disposed so as to perform heating from a side of the support member 11 (the side opposite to the other surface 102 of the workpiece 10), heat may be efficiently transferred to the support member 11.

As illustrated in FIG. 6, in the second embodiment of the shrinkage step, a protective sheet 36 is laid on the upper surface of the holding table 35, and the frame 12 is placed on an upper surface of the protective sheet 36 in a state in which the other surface 102 of the workpiece 10 faces downwards and the support member 11 faces upwards. The protective sheet 36 is made of a resin material such as polyethylene terephthalate (PET) or polyolefin, and protects the chips 14 from coming into direct contact with the holding table 35. In the configuration example of FIG. 6, a thickness of the frame 12 is larger than a thickness of the workpiece 10, and the workpiece 10 is supported above the protective sheet 36 in a state in which the other surface 102 is separated from the protective sheet 36.

A heating member 37 is disposed above the holding table 35. The holding table 35 and the heating member 37 are relatively movable in the X-axis direction and the Y-axis direction. For example, the holding table 35 may be configured to move in the X-axis direction, and the heating member 37 may be configured to move in the Y-axis direction. The heating member 37 injects hot air or emits infrared rays downwards. That is, the region immediately below the heating member 37 may be heated locally.

When an imaging unit 38 disposed above the holding table 35 captures an image of the workpiece 10 through the support member 11 and detects the position of the division groove 13, the heating member 37 is positioned above the detected division groove 13, and heat is applied by injecting hot air or emitting infrared rays from the heating member 37, a region of the support member 11 located above the division groove 13 is heated and shrinks. The position of the division groove 13 moves due to shrinkage of the support member 11. Therefore, while the holding table 35 and the heating member 37 are moved relatively in the X-axis direction, by repeating the acts of detecting of the division groove 13 by the imaging unit 38, locating the heating member 37 to the position corresponding to the division groove 13, and heating of the support member 11 by the heating member 37, the support member 11 shrinks in the region along the division groove 13 extending in the X-axis direction.

After the workpiece 10 is heated by the heating member 37 along the single division groove 13, the imaging unit 38 captures an image of the workpiece 10 to detect the position of the next division groove 13 which is not yet shrunk, the holding table 35 and the heating member 37 are relatively moved in the Y-axis direction, and the heating member 37 is positioned above the detected division groove 13. Thereafter, by relatively moving the holding table 35 and the heating member 37 in the X-axis direction while heating the workpiece 10 by the heating member 37, the support member 11 shrinks in the region along the next division groove 13.

Optionally, as a heating unit in place of the heating member 37, an elongated heating unit extending to a length equal to or greater than a diameter of the workpiece 10 in the X-axis direction may be provided. In the case where this heating unit is used, since a range along the entire division groove 13 extending in the X-axis direction may be heated by the heating unit, the operation to relatively move the holding table 35 and the heating member 37 in the X-axis direction as described above may not be needed. Therefore, the region corresponding to each of the division grooves 13 in the support member 11 may be efficiently heated.

After the support member 11 shrinks by being heated by the heating member 37 along all the division grooves 13 extending in the X-axis direction, the holding table 35 is rotated by 90°. Accordingly, the support member 11 is placed in an orientation such that the plurality of division grooves 13 not yet shrunk extend in the X-axis direction (arrayed at intervals in the Y-axis direction). In this orientation, by being heated with the heating member 37 along each of the division grooves 13 extending in the X-axis direction, the support member 11 shrinks in the same procedure as described above.

As shown in FIG. 6, when the support member 11 shrinks in the region heated by the heating member 37, the width of the division groove 13 is reduced. FIG. 6 illustrates a stage at which the support member 11 is shrunk to a region corresponding to the two division grooves 13 on the left side in the drawing, and the support member 11 is not yet shrunk in the division grooves 13 on the right side of the region.

As described above, since the heating member 37 heats the support member 11 only in a specific region along the division groove 13, the support member 11 may reliably shrink in a region along each division groove 13, and the support member 11 may be suppressed from shrinking in an intermediate region (a region corresponding to the chip 14) between the division grooves 13. Moreover, since the heating member 37 applies the heat from the side of the support member 11 (the side opposite to the other surface 102 of the workpiece 10), the support member 11 may be efficiently heated.

### [Burr Removal Step]

Following the shrinkage step, a burr removal step shown in FIG. 7 is performed. The burr removal step is performed using the holding table 40 and a water jet type processing device including the high-pressure water injection nozzle 41.

In the burr removal step, the workpiece 10 and the support member 11 are placed on the holding table 40. Specifically, the lower surface of the support member 11 is placed on the upper surface of the holding table 40 in a state in which the other surface 102 of the workpicce 10 faces upwards and the support member 11 faces downwards. The holding table 40 includes a suction mechanism that suctions and holds the support member 11 and a clamp portion that clamps the frame 12, and the workpiece 10 is fixedly held on the holding table 40.

The high-pressure water injection nozzle 41 is located above the holding table 40. The high-pressure water injection nozzle 41 forms the water jet type processing unit, and high-pressure water W obtained by increasing the pressure of the water supplied from a high-pressure water supply source 42 to a pressure suitable for removing a burr is injected downwards from the high-pressure water injection nozzle 41. That is, the high-pressure water W is injected from the side of the other surface 102 of the workpiece 10 along the division groove 13.

The pressure of the high-pressure water W suitable for removing the burr is a pressure, which is substantially intense to remove a minute burr 15 formed on the workpiece 10 by force of the high-pressure water W but not to damage the chip 14. Such an appropriate pressure of the high-pressure water W is calculated in advance and stored in a storage unit included in a controller of the processing device that performs the burr removal step. As for an injection time of the high-pressure water W per unit area of the workpiece 10, an appropriate injection time is calculated in advance so that the burr 15 may be removed and the chip 14 is not damaged, and is stored in the storage unit included in the controller of the processing device.

The holding table 40 and the high-pressure water injection nozzle 41 are relatively movable in the X-axis direction and the Y-axis direction. For example, the holding table 40 may be configured to move in the X-axis direction, and the high-pressure water injection nozzle 41 may be configured to move in the Y-axis direction.

The burr removal step is performed in a state in which the image of the workpiece 10 is captured by the imaging unit 43 disposed above the holding table 40, a position of the division groove 13 is detected, and the high-pressure water injection nozzle 41 is positioned above the detected division groove 13. With the high-pressure water injection nozzle 41 being positioned above the division groove 13 detected by the imaging unit 43, when the high-pressure water W is injected from the high-pressure water injection nozzle 41, the burr 15 is removed in a region on the other surface 102 of the workpiece 10 on which the high-pressure water W hits. By relatively moving the holding table 40 and the high-pressure water injection nozzle 41 in the X-axis direction while injecting the high-pressure water W from the high-pressure water injection nozzle 41, the burr 15 is removed in the region along the division groove 13 extending in the X-axis direction.

After the burr 15 is removed along the one of the division grooves 13, the imaging unit 43 captures of another image of the workpiece 10 to detect a position of the next division groove 13, the holding table 40 and the high-pressure water injection nozzle 41 are relatively moved in the Y-axis direction, and the high-pressure water injection nozzle 41 is positioned above the detected division groove 13. Thereafter, by relatively moving the holding table 40 and the high-pressure water injection nozzle 41 in the X-axis direction while injecting the high-pressure water W from the high-pressure water injection nozzle 41, the burr 15 is removed in the region along the next division groove 13.

After the burrs 15 are removed by injecting the high-pressure water W from the high-pressure water injection nozzle 41 along all the division grooves 13 extending in the X-axis direction, the holding table 40 is rotated by 90°. Accordingly, the plurality of division grooves 13, of which burrs 15 are not yet removed, extend in the X-axis direction (arrayed at intervals in the Y-axis direction), and the high-pressure water W is injected from the high-pressure water injection nozzle 41 along each of the division grooves 13 extending in the X-axis direction so as to remove the burrs 15 in the same procedure as described above.

In the previous shrinkage step, since the width of the division groove 13 is reduced by causing shrinkage in at least the region corresponding to the division groove 13 in the support member 11, most of the high-pressure water W injected at the workpiece 10 for removing the burr 15 hits the other surface 102 of the workpiece 10 and may scatter in the surroundings, and the high-pressure water W to enter the division groove 13 may be reduced. Even if the water enters the division grooves 13, since the width of the division groove 13 is reduced, intensity of the water entering the division groove 13 is lower than that of the high-pressure water W. Therefore, the high-pressure water W may be prevented from passing through the division groove 13 and reaching the support member 11 with the intense force and directly hitting the support member 11, and the support member 11 may be prevented from having a hole being formed therein by the injection of the high-pressure water W. Further, since the high-pressure water W having the intense force may not reach the holding surface of the holding table 40 located below the support member 11, the holding surface of the holding table 40 may be prevented from having a hole being formed therein by the injection of the high-pressure water W. In other words, lowering the pressure of the high-pressure water W is not needed in order to prevent the damage in the support member 11 and the holding table 40, and the high-pressure water W having the sufficient pressure for removing the burr 15 may be injected.

Moreover, when the high-pressure water W is injected in a state in which the width of the division groove 13 is reduced, the injection region of the high-pressure water W (injection width of the high-pressure water W in the Y-axis direction) may easily cover both edges of the division groove 13 in the width direction, and the burrs 15 on both edges of the division groove 13 may be collectively removed, so that the burrs 15 may be efficiently removed by injecting the high-pressure water W at each division groove 13 at a time.

For example, if the shrinkage step is not performed (that is, the width of the division groove 13 is not reduced), the injection region of the high-pressure water W may not cover both edges of the division groove 13, and the high-pressure water W may be injected back and forth for each edge of a single division groove 13, so that it may take extra time to remove the burrs 15 from both edges of the division groove 13.

As described above, by performing the burr removal step after the shrinkage step, the burrs 15 may be efficiently removed by injecting the high-pressure water W without damaging the support member 11. When the burr removal step is completed, the workpiece 10 is removed out from the holding table 40 to complete the series of processes.

The workpiece 10 from which the burrs have been removed is conveyed to a die bonder device (not illustrated), and the plurality of divided chips 14 are picked up. In general, for being picked up, the plurality of chips 14 are required to be located separately at a predetermined interval. Therefore, after the burr removal step, a re-expansion step of releasing the support member 11 from shrinkage and widening the widths of the division grooves 13 again may be performed. For example, the widths of the division grooves 13 may be re-expanded by extending the support member 11 in the radial expansion direction using an expansion mechanism capable of applying tension in the radial expansion direction to the support member 11. For another example, the plurality of chips 14 may be transferred from the support member 11 to be bonded to another support member at a predetermined interval so as to increase the interval between the chips 14.

In the above embodiment, the heat shrinkable support member 11 is used, and the support member 11 is heated to cause shrinkage thereof in the shrinkage step, but the method to cause shrinkage in the support member in the shrinkage step is not necessarily limited thereto.

For example, as a modification, a support member of a type that shrinks by being exposed to an electromagnetic wave (ultraviolet ray or the like), a support member of a type that shrinks by being cooled, or the like, may be used. In these types of support members, irradiating the electromagnetic wave and cooling work as applying an external force that causes shrinkage to the support member.

For another example, a holding table (for example, the holding table 40 or the like used in the burr removal step illustrated in FIG. 7) that holds the workpiece may include a suction mechanism capable of suctioning and drawing the support member in a region corresponding to the division groove. By the suction mechanism, the support member may shrink by being partially drawn against the holding table, and the width of the division groove may be reduced. Further, by releasing the support member from the suction force by the suction mechanism of the holding table, the width of the division groove may return to the original width. That is, in this modification, applying the suction force to the support member works as applying the external force that causes shrinkage to the support member.

In the above embodiment, the division groove 13 is formed in the workpiece 10 using the cutting blade 24, but the method of forming the division groove in the workpiece is not limited thereto. For example, the division groove may be formed in the workpiece by laser processing or water jet processing. That is, any processing method may be widely applied as long as a burr is likely to be created along the edge of the division groove when the division groove is formed.

In the above embodiment, forming of the division grooves 13 and removal of the burrs 15 are performed to a workpiece unit, which includes the frame 12 attached to the peripheral edges of the support member 11 that supports the workpiece 10. However, a workpiece unit may not necessarily include the frame 12, and forming of the division grooves 13 and removal of the burrs 15 may be performed to the workpiece unit consisting only of the workpiece 10 and the support member 11.

It is noted that the embodiments of the present invention are not limited to those described above, but various changes, substitutions, and modifications may be made without departing from the spirit of the technical idea of the present invention. Furthermore, if the technical idea of the present invention are expressible in another manner by a progress of the technology or another derived technology, the technical idea may be implemented by using the method. Therefore, the claims cover all implementations that may be included within the scope of the technical idea of the present invention.

As described above, the processing method for the workpiece of the present invention may remove the burr without damaging the support member when the high-pressure water is injected along the division groove, and is usable in the technical field of dividing the workpiece to produce a plurality of chips and the like.

This disclosure includes the following inventions.

### (Additional Note 1)

A processing system configured to process a workpiece, comprising:
a support member configured to support the workpiece having a division groove formed therein along a division preparatory line, the supporting member supporting the workpiece by a surface of the workpiece on one side being fixed thereto;
an external force applier configured to apply external force to at least a region of the support member corresponding to the division groove, the external force causing the support member to shrink and reducing a width of the division groove supported on the support member; and
a water jet injector configured to remove a burr from the workpiece by injecting high-pressure water along the division groove, of which width being reduced by shrinkage of the support member, from the other side of the workpiece.

### (Additional Note 2)

The processing system according to additional note 1, wherein the external force applier is a heater configured to apply heat to the support member.

What is claimed is:

1. A processing method for a workpiece, comprising:
preparing the workpiece by fixing a surface of the workpiece on one side to a support member, the workpiece having a division groove formed therein along a division preparatory line;
reducing a width of the division groove by applying external force to at least a region of the support member corresponding to the division groove to cause shrinkage in the support member; and
removing a burr from the workpiece by injecting, after the support member being shrunk, high-pressure water along the division groove from the other side of the workpiece.

2. The processing method according to claim 1, wherein heat is applied to the support member to cause the shrinkage.
